(19) United States
(12) Patent Application Publication
(10) Pub. No.: US 2026/0030422 A1
(43) Pub. Date: Jan. 29, 2026

(54) I2C REGISTER MAP WITH VIRTUAL EXTENSION

(71) Applicant: TRINAMIX GMBH, Ludwigshafen Am Rhein (DE)

(72) Inventor: Jonas RAHLF, Ludwigshafen am Rhein (DE)

(21) Appl. No.: 18/995,224

(22) PCT Filed: Aug. 15, 2023
(86) PCT No.: PCT/EP23/72435

§ 371 Date: Jan. 16, 2025

(30) Foreign Application Priority Data
Aug. 16, 2022 (EP) 22190603.5

(51) Int. Cl. G06F 30/327

(52) U.S. Cl. CPC G06F 30/327

(57) ABSTRACT

Disclosed herein is a system including at least one inter-integrated circuit node (I2C node), at least one master controller and at least one inter-integrated circuit (I2C). The I2C is configured for transmitting data between the I2C node and the master controller. The I2C node provides a register map. The master controller is configured for reading the register map byte-wise. The I2C node is configured for incrementing a register address after every byte. The register map includes a physical register map. Data of the physical register map have a physical address in a memory of the I2C node. The I2C node is configured for generating data which size is larger than the physical register map. The register map includes a virtual section, where data of the virtual section have an address in a further memory location. The master controller is configured for reading the virtual section by performing a transaction which starts in the physical register map and increasing the register address beyond the physical register map size.

### TECHNICAL FIELD

The invention relates to a system comprising at least one inter-integrated circuit node (I2C node), a mobile device, a method for data transmission between at least one I2C node and at least one master controller and several uses. Such methods and devices can, in general, be used for investigation or monitoring purposes, in particular in the infrared (IR) spectral region, especially in the near-infrared (NIR) spectral region, as well as for a detection of heat, flames, fire, or smoke. However, further kinds of applications are possible.

### BACKGROUND ART

Infrared spectrometer can be built into a mobile device, for example a smartphone. Such a spectrometer usually may comprise a number of IR sensors (also denoted as pixels) each with different wavelength filter, so each sensor can measure the light intensity at a certain wavelength. The thus acquired data may be needed to be transferred to the mobile device, so that its processing unit, in particular its central processing unit (CPU) can further process the data. One often uses a so called inter-integrated circuit (I2C) protocol for data transfer in mobile devices which was designed for relatively simple components transferring little data.

Semiconductor Corporation Cypress: “Master Slave 1.20”, PSoC Creator Component Data Sheet, 2015 Dec. 20, pages 1-36, XP093019583, gives a general description of I2C slave and master configuration.

Usually, an I2C node, e.g. a sensor module, may provide a standard 8-bit register map. For example, the I2C node may generate data which size is larger than the register map, e.g. more than 256 Byte, size N>256. A master can read and write into the register map byte-wise and the node automatically may increment the address after every byte so that a single transaction can include more than one byte.

For spectrometers, however the data quickly may become very large. This is because there are different sensors (pixels) each providing values. In addition, several measurements may be performed to improve the signal. Thus, fast readout of the generated data may be problematic and may be performed using complex techniques.

### Problem to be Solved

Therefore, the problem addressed by the present invention is that of providing a system, a mobile device, a method for data transmission which at least substantially avoid the disadvantages of known methods and devices of this type. In particular, it is desirable to provide methods and devices which ensure fast data readout in a simple fashion.

### SUMMARY

This problem is addressed by a system, a mobile device, a method for data transmission with the features of the independent claims. Advantageous embodiments which might be realized in an isolated fashion or in any arbitrary combinations are listed in the dependent claims as well as throughout the specification.

In a first aspect of the present invention, a system comprising at least one inter-integrated circuit node (I2C node), at least one master controller and at least one inter-integrated circuit (I2C) is disclosed. The I2C is configured for transmitting data between the I2C node and the master controller. The I2C node provides a register map. The master controller is configured for reading the register map byte-wise. The I2C node is configured for incrementing a register address after every byte. The register map comprises a physical register map. Data of the physical register map have a physical address in a memory of the I2C node. The I2C node is configured for generating data which size is larger than the physical register map. The register map comprises a virtual section. Data of the virtual section have an address in a further memory location. The master controller is configured for reading the virtual section by performing a transaction which starts in the physical register map. A transaction length of the transaction extends beyond the physical register map size. In particular, the transaction starts at the start address and the transaction length is greater than the size of the physical register map.

The term “system” as used herein is a broad term and is to be given its ordinary and customary meaning to a person of ordinary skill in the art and is not to be limited to a special or customized meaning. The term specifically may refer, without limitation, to an arbitrary set of interacting or interdependent components parts forming a whole. Specifically, the components may interact with each other in order to fulfill at least one common function. The at least two components may be handled independently or may be coupled or connectable. The system comprises at least one inter-integrated circuit node (I2C node), at least one master controller and at least one inter-integrated circuit (I2C).

The term “inter-integrated circuit” as used herein is a broad term and is to be given its ordinary and customary meaning to a person of ordinary skill in the art and is not to be limited to a special or customized meaning. The term specifically may refer, without limitation, to a data bus configured for connecting integrated circuits. For example, the I2C may be designed as described in https://www.nxp.com/docs/en/user-guide/UM10204.pdf, www.ipd.kit.edu/˜buchmann/microcontroller/i2c.htm, or in www.ti.com/lit/an/slva704/slva704.pdf. The I2C may be a synchronous, packet switched, single-ended, serial communication bus. Specifically, the I2C is a hierarchical bus system having a so-called master-slave architecture comprising at least one master controller and at least one I2C node.

The system may comprise one or more I2C nodes. The term “I2C node”, also denoted as slave, as used herein is a broad term and is to be given its ordinary and customary meaning to a person of ordinary skill in the art and is not to be limited to a special or customized meaning. The term specifically may refer, without limitation, to an arbitrary I2C device connected to the I2C bus. For example, the I2C node comprises at least one sensor. The sensor may comprise at least one element selected from the group consisting of: at least one spectrometer, at least one multi-channel IR sensor, at least one multi-channel photo sensor, any sensor with data buffer and automatic data accumulation (smart sensor). For example, the I2C node is a spectrometer. The spectrometer may comprise a number of pixels each with different wavelength filter, so each pixel can measure the light intensity at a certain wavelength. The I2C node further may comprise at least one processor such as at least one microprocessor, at least one microcontroller and/or at least one computer.

The term “processor” as used herein is a broad term and is to be given its ordinary and customary meaning to a person of ordinary skill in the art and is not to be limited to a special or customized meaning. The term specifically may refer, without limitation, to an arbitrary logic circuitry configured for performing basic operations of a computer or system, and/or, generally, to a device which is configured for performing calculations or logic operations. In particular, the processor may be configured for processing basic instructions that drive the computer or system. As an example, the processor may comprise at least one arithmetic logic unit (ALU), at least one floating-point unit (FPU), such as a math co-processor or a numeric co-processor, a plurality of registers, specifically registers configured for supplying operands to the ALU and storing results of operations, and a memory, such as an L1 and L2 cache memory. In particular, the processor may be a multi-core processor. Specifically, the processor may be or may comprise a central processing unit (CPU). The processor may be or may comprise a microprocessor, thus specifically the processor's elements may be contained in one single integrated circuitry (IC) chip. The processor may further comprise one or more application-specific integrated circuits (ASICs) and/or one or more field-programmable gate arrays (FPGAs) and/or one or more tensor processing unit (TPU) and/or one or more chip, such as a dedicated machine learning optimized chip, or the like. The processor specifically may be configured, such as by software programming, for performing one or more evaluation operations.

The system may comprise one or more master controllers. The term “master controller”, also denoted as master, as used herein is a broad term and is to be given its ordinary and customary meaning to a person of ordinary skill in the art and is not to be limited to a special or customized meaning. The term specifically may refer, without limitation, to at least one processor such as at least one microprocessor, at least one microcontroller and/or at least one computer assigned to be master of the system. The master controller may be configured for addressing the one or more I2C nodes, wherein the reverse is not possible.

The I2C is configured for transmitting data between the I2C node and the master controller. The transmission may comprise a data exchange. Data may be transferred in sequences of 8 bits. During each clock cycle one data bit may be transferred.

The I2C bus may be based on two lines, wherein one of the lines is used for transporting a clock signal (serial clock line, SCL) and the other one is used for transmitting data bits (serial data line, SDA). The clock signal may be generated by the master controller. The master controller may be configured for initiating data transmission by sending a query to an I2C node. To start a data transmission, the master controller may be configured for specifying an address of the I2C node to or from which it wants to exchange data. Each I2C node may comprise an, in particular 4-bit, address hard-wired into a chip of the I2C node. In addition, the chip of each I2C node may comprise a plurality of address pins, which can be assigned with any address. For addressing the respective I2C node a plurality of bits, e.g. 7 bits, may be used and transferred. At least one further bit may be used for specifying whether the master controller is to transmit data to the I2C node (i.e. write) or to receive data from the I2C node (i.e. read). As described in www.ti.com/lit/an/slva704/slva704.pdf, a procedure for the master controller to read data from the I2C node may be as follows
the master controller sends a START condition and addresses the I2C node, wherein a high-to-low transition on the SDA line while the SCL is high defines a START condition;
the master controller sends the requested register to read from to the I2C node;
the master controller receives data from the I2C node;
the master controller terminates the transfer with a STOP condition, wherein a low-to-high transition on the SDA line while the SCL is high defines a STOP condition.

The I2C node may comprise one or more registers. The term “register”, as used herein is a broad term and is to be given its ordinary and customary meaning to a person of ordinary skill in the art and is not to be limited to a special or customized meaning. The term specifically may refer, without limitation, to a location in a memory of the I2C node configured for storing information. The information may be configuration information and/or data obtained by the at least one sensor of the I2C node. The information stored within the register may be values, in particular one or more of measurement values, measurement uncertainties, calibration values, (system) configuration values, measurement parameters. Each of the registers may have a unique address. Each of the registers may comprise 8 bits. The master controller is configured for reading, and optionally writing into, the register map byte-wise. The master controller can read and write into the register map byte-wise. The I2C node is configured for incrementing a register address after every byte.

Usually, reading from a register may be performed as follows, e.g. as described in www.ti.com/lit/an/slva704/slva704.pdf. The master controller may be configured for instructing the I2C node from which register map it wishes to read from. The master controller may be configured for starting off the transmission by sending the address with the bit signifying a write, followed by the register address it wishes to read from. After the I2C node acknowledges this register address, the master controller may send a START condition again, followed by the I2C node address with the bit signifying a read. The I2C node may acknowledge the read request. The master controller may continue sending out the clock pulses, but will release the SDA line, so that the I2C node can transmit data. At the end of every Byte of data, the master controller may send an ACK (acknowledge) to the I2C node, letting the I2C node know that it is ready for more data. Once the master controller may have received the number of bytes it is expecting, it will send a NACK (Not Acknowledge), signaling to the I2C node to halt communications and release the bus. The master controller may follow this up with a STOP condition. The master controller can read and write into the register map byte-wise. The I2C node may be configured for automatically incrementing the address after every byte so that a single transaction can include more than one byte.

The I2C node provides a register map. The term “register map”, as used herein is a broad term and is to be given its ordinary and customary meaning to a person of ordinary skill in the art and is not to be limited to a special or customized meaning. The term specifically may refer, without limitation, to an ordered list of registers. The I2C node may comprise one or more registers. Each of the registers may have a unique address. The register map may comprise a register map layout. The register map may comprise a plurality of columns and rows. The register map may comprise an index N for each register. For example, the register map may comprise two columns, wherein in a first column the index and in a second column a register name is listed. The register map may comprise a size. The size of the index N may be equal to the size of the register map.

The register map comprises a physical register map. Data of the physical register map have a physical address in a memory of the I2C node. The I2C node is configured for generating data which size is larger than the physical register map. The term “physical register map”, as used herein is a broad term and is to be given its ordinary and customary meaning to a person of ordinary skill in the art and is not to be limited to a special or customized meaning. The term specifically may refer, without limitation, to a part of the register map comprising registers having a physical address in a memory of the I2C node. The term “memory”, as used herein is a broad term and is to be given its ordinary and customary meaning to a person of ordinary skill in the art and is not to be limited to a special or customized meaning. The term specifically may refer, without limitation, to a device or system configured for storing data. The memory of the I2C node may comprise semiconductor memory. The memory of the I2C node may comprise volatile and/or non-volatile memory. For example, the memory of the I2C node may comprise one or more of RAM such as dynamic random-access memory (DRAM) or static random-access memory (SRAM). For example, the memory of the I2C node may comprise one or more of flash memory, ROM, PROM, EPROM, EEPROM memory and Ferroelectric random-access memory (FRAM). The physical register map may comprise a physical register map size. The I2C node is configured for providing the physical register map as a standard 8-bit register map. The physical register map size may be N≤256. The I2C node may be configured for generating data which size N is >256 Byte.

Usually, the size of the physical register map size is 256 Byte, wherein the index N may run from 0 to 255. However, the I2C node may generate data which size is larger than the physical register map (e.g. more than 256 Byte) (size N>256). In this case, for example, the register map size may be increased. However, this may not be possible under certain circumstances e.g. in case the I2C node does not have enough RAM or the register address size is fixed to 8-bit due to software compatibility. Additionally or alternatively, the register map may be partitioned into smaller sizes and data transmission may be performed using multiple transactions. For example, the data is partitioned into smaller sizes that fit into the register map, e.g. in sizes of 128 Byte values. The register map may comprise a special control register named “partition index” which controls which partition is accessed by the master controller. To read all data, the master controller may first perform a write transaction to the partition index followed by a read transaction which can transport up to 254 Bytes. This pair of transactions must be performed multiple times, until all data is transferred. Thus, if the data is partitioned and a partition index is used, then multiple transactions must be performed. However, in case of partitioning gaps in the transfer between the transactions. Between every transaction is a gap, due to one or more of a) the bus possibly being used for another sensor, b) natural processing delay, i.e. starting a new transaction takes several CPU cycles and c) the process requesting the next transfer sleeping and waiting to be scheduled again (on systems with operating system). The contribution of a) and b) mainly depend on the system load and the processor performance. Depending on the number of bytes and the operating system, these gaps can become significant (e.g. non real time operating system like Linux, Android).

Specifically, in order to allow fast readout although the I2C node generating data which size is larger than the physical register map, the present invention proposes the register map comprising a virtual section. The register map may be extended virtually. Data of the virtual section have an address in a further memory location. The term “virtual section”, as used herein is a broad term and is to be given its ordinary and customary meaning to a person of ordinary skill in the art and is not to be limited to a special or customized meaning. The term specifically may refer, without limitation, to a further part of the register map, i.e. in addition to the physical register map, comprising registers having an address in a further memory location. The term “further memory location”, as used herein is a broad term and is to be given its ordinary and customary meaning to a person of ordinary skill in the art and is not to be limited to a special or customized meaning. The term specifically may refer, without limitation, to an arbitrary memory location different from the memory comprising data relating to the physical register map. The further memory location may be a physical storage location of the I2C node different from the memory and/or the further memory location may be a memory location external from the I2C node. The further memory location may be a memory location where all data is available in contiguous form. Due to the contiguous form, the I2C node can provide all data for reading in a single transaction.

The virtual section cannot be addressed directly. The master controller is configured for reading the virtual section by performing a transaction which starts in the physical register map. A transaction length of the transaction extends beyond the physical register map size. In particular, the transaction starts at the start address and the transaction length is greater than the size of the physical register map. To read all data generated by the I2C node, the master controller may start reading the first value (e.g. register address 0) and may keep reading even after reading value 255 until all data of the registers of the virtual section, e.g. values 256 to N with N>256, is transferred. By this technique, all data is transferred in a single read transaction. Extending the register map virtually may allow providing the fastest possible solution to transfer all data.

As outlined above, the I2C node may be configured for automatically incrementing the address after every Byte. When the address reaches the end of the physical register map, it cannot fetch the data from the next consecutive physical address. The I2C node may be configured for providing the next data from the first register of the virtual section. The I2C node may be configured for providing the next data, when the register address reaches the end of the physical register map, by translating between the address in the further memory location and a physical address in the memory.

For example, the I2C node may be configured for filling the physical register map with values from the virtual section and for resetting the physical address back to zero, when the register address reaches the end of the physical register map. This process may be transparent for the master controller. The master controller may be configured for reading as many values and/or bytes from the virtual section as required and/or as predefined, e.g. through a driver. This process may occur whenever the address in the further memory location reaches a multiple of the size of the physical register map. The I2C node may be configured for updating and/or refilling the physical register map with the original values for page 0, after the transfer is completed.

The I2C node may be configured for operating with at least one special register. The I2C node may be configured for operating with multiple special registers. The virtual extension of the physical register map may only be available if the read starts from a special register (or one of multiple special registers). The term “special register”, as used herein is a broad term and is to be given its ordinary and customary meaning to a person of ordinary skill in the art and is not to be limited to a special or customized meaning. The term specifically may refer, without limitation, to a register of the physical register map having a predefined and/or preassigned function. The special register may be any register or multiple register in the physical register map. For example, the special register may be register 0 or the final register of the physical register map. For example, the special register may be placed after all register values (if there are any) of the physical register map. The I2C node may be configured for providing data which are stored in the further memory location, if the master controller starts reading said special register. This may also be transparent for the master controller. For example, once the master controller may start reading exactly the special register, the I2C node may send data internally which are stored in a different storage location. If the read starts from the special register, the I2C node may fetch data not from the physical register map, but instead from a special memory location where all data is available in contiguous form. The address in the further memory location may be defined by another register, e.g. an offset from the location of the special register.

In a further aspect, a mobile device comprising at least one system according to the present invention, such as according to any one of the embodiments relating to a system as described above or in more detail below, is disclosed. For further details regarding to the mobile device reference may be made to the description of the system above and as described in more detail below. The mobile device is at least one element selected from the group consisting of: a notebook computer, a tablet, a cell phone, a smart phone, a smartwatch and a wearable computer. The mobile device is configured for using at least one I2C protocol for data transfer within the mobile device.

In a further aspect, a method for data transmission between at least one inter-integrated circuit node (I2C node) and at least one master controller is disclosed. The method comprises using a system according to the present invention such as according to any one of the embodiments relating to a system as described above or in more detail below. The method comprises the following steps:
generating data which size is larger than the physical register map and providing the register map by using the I2C node;
reading the register map byte-wise by using the master controller and incrementing a register address after every byte by using the I2C node,
reading the virtual section of the register map by performing a transaction which starts in the physical register map by using the master controller, wherein a transaction length of the transaction extends the register address beyond the physical register map size.

The method steps may be performed in the indicated order. It shall be noted, however, that a different order is also possible. The method may comprise further method steps which are not listed. Further, one or more of the method steps may be performed once or repeatedly. Further, two or more of the method steps may be performed simultaneously or in a timely overlapping fashion. The method may comprise repeating steps at pre-defined times or continuously.

The method may be computer-implemented. The term “computer implemented method” as used herein is a broad term and is to be given its ordinary and customary meaning to a person of ordinary skill in the art and is not to be limited to a special or customized meaning. The term specifically may refer, without limitation, to a method involving at least one computer and/or at least one computer network. The computer and/or computer network may comprise at least one processor which is configured for performing at least one of the method steps of the method according to the present invention. Specifically, each of the method steps is performed by the computer and/or computer network. The method may be performed completely automatically, specifically without user interaction.

The method may comprise transmission of sensor data generated by the I2C node. The I2C node may comprise at least one sensor. The sensor may comprise at least one element selected from the group consisting of: at least one spectrometer, at least one multi-channel IR sensor, at least one multi-channel photo sensor, any sensor with data buffer and automatic data accumulation. For example, the I2C node is a spectrometer. The spectrometer may comprise a number of pixels each with different wavelength filter, so each pixel can measure the light intensity at a certain wavelength.

The I2C node may provide the next data, when the register address reaches the end of the physical register map, by translating between the address in the further memory location and a physical address in the memory.

When the register address reaches the end of the physical register map, the I2C node may fill the physical register map with values from the virtual section and resets the physical address back to zero. This process may be transparent for the master controller. The master controller may read as many values and/or bytes from the virtual section as required and/or as predefined, e.g. by a driver. This process may occur whenever the address in the further memory location reaches a multiple of the size of the physical register map.

The I2C node may operate with at least one special register. If the master controller starts reading said special register, the I2C node may provide data which are stored in the further memory location. This process may be transparent for the master controller.

Further disclosed and proposed herein is a computer program including computer-executable instructions for performing the method according to the present invention in one or more of the embodiments enclosed herein when the program is executed on a computer or computer network. Specifically, the computer program may be stored on a computer-readable data carrier and/or on a computer-readable storage medium.

As used herein, the terms “computer-readable data carrier” and “computer-readable storage medium” specifically may refer to non-transitory data storage means, such as a hardware storage medium having stored thereon computer-executable instructions. The computer-readable data carrier or storage medium specifically may be or may comprise a storage medium such as a random-access memory (RAM) and/or a read-only memory (ROM).

Thus, specifically, one, more than one or even all of method steps as indicated above may be performed by using a computer or a computer network, preferably by using a computer program.

Further disclosed and proposed herein is a computer program product having program code means, in order to perform the method according to the present invention in one or more of the embodiments enclosed herein when the program is executed on a computer or computer network. Specifically, the program code means may be stored on a computer-readable data carrier and/or on a computer-readable storage medium.

Further disclosed and proposed herein is a data carrier having a data structure stored thereon, which, after loading into a computer or computer network, such as into a working memory or main memory of the computer or computer network, may execute the method according to one or more of the embodiments disclosed herein.

Further disclosed and proposed herein is a computer program product with program code means stored on a machine-readable carrier, in order to perform the method according to one or more of the embodiments disclosed herein, when the program is executed on a computer or computer network. As used herein, a computer program product refers to the program as a tradable product. The product may generally exist in an arbitrary format, such as in a paper format, or on a computer-readable data carrier and/or on a computer-readable storage medium. Specifically, the computer program product may be distributed over a data network.

Finally, disclosed and proposed herein is a modulated data signal which contains instructions readable by a computer system or computer network, for performing the method according to one or more of the embodiments disclosed herein.

Referring to the computer-implemented aspects of the invention, one or more of the method steps or even all of the method steps of the method according to one or more of the embodiments disclosed herein may be performed by using a computer or computer network. Thus, generally, any of the method steps including provision and/or manipulation of data may be performed by using a computer or computer network. Generally, these method steps may include any of the method steps, typically except for method steps requiring manual work, such as providing the samples and/or certain aspects of performing the actual measurements.

Specifically, further disclosed herein are:
a computer or computer network comprising at least one processor, wherein the processor is adapted to perform the method according to one of the embodiments described in this description,
a computer loadable data structure that is adapted to perform the method according to one of the embodiments described in this description while the data structure is being executed on a computer,
a computer program, wherein the computer program is adapted to perform the method according to one of the embodiments described in this description while the program is being executed on a computer,
a computer program comprising program means for performing the method according to one of the embodiments described in this description while the computer program is being executed on a computer or on a computer network,
a computer program comprising program means according to the preceding embodiment, wherein the program means are stored on a storage medium readable to a computer,
a storage medium, wherein a data structure is stored on the storage medium and wherein the data structure is adapted to perform the method according to one of the embodiments described in this description after having been loaded into a main and/or working storage of a computer or of a computer network, and
a computer program product having program code means, wherein the program code means can be stored or are stored on a storage medium, for performing the method according to one of the embodiments described in this description, if the program code means are executed on a computer or on a computer network.

In a further aspect of the present invention, a use of a system according to any one of the embodiments described above or below in further detail referring to a system is disclosed for a purpose of use, selected from the group consisting of: an infrared detection application; a heat detection application; a thermometer application; a heat-seeking application; a flame-detection application; a fire-detection application; a smoke-detection application; a temperature sensing application; a spectroscopy application; an exhaust gas monitoring application; a combustion process monitoring application; a pollution monitoring application; an industrial process monitoring application; a chemical process monitoring application; a food processing process monitoring application; a water quality monitoring application; an air quality monitoring application; a quality control application; a temperature control application; a motion control application; an exhaust control application; a gas sensing application; a gas analytics application; a motion sensing application; a chemical sensing application; a mobile application; a medical application; a mobile spectroscopy application; a food analysis application.

As used herein, the terms “have”, “comprise” or “include” or any arbitrary grammatical variations thereof are used in a non-exclusive way. Thus, these terms may both refer to a situation in which, besides the feature introduced by these terms, no further features are present in the entity described in this context and to a situation in which one or more further features are present. As an example, the expressions “A has B”, “A comprises B” and “A includes B” may both refer to a situation in which, besides B, no other element is present in A (i.e. a situation in which A solely and exclusively consists of B) and to a situation in which, besides B, one or more further elements are present in entity A, such as element C, elements C and D or even further elements.

Further, it shall be noted that the terms “at least one”, “one or more” or similar expressions indicating that a feature or element may be present once or more than once typically are used only once when introducing the respective feature or element. In most cases, when referring to the respective feature or element, the expressions “at least one” or “one or more” are not repeated, nonwithstanding the fact that the respective feature or element may be present once or more than once.

Further, as used herein, the terms “preferably”, “more preferably”, “particularly”, “more particularly”, “specifically”, “more specifically” or similar terms are used in conjunction with optional features, without restricting alternative possibilities. Thus, features introduced by these terms are optional features and are not intended to restrict the scope of the claims in any way. The invention may, as the skilled person will recognize, be performed by using alternative features. Similarly, features introduced by “in an embodiment of the invention” or similar expressions are intended to be optional features, without any restriction regarding alternative embodiments of the invention, without any restrictions regarding the scope of the invention and without any restriction regarding the possibility of combining the features introduced in such way with other optional or non-optional features of the invention.

Summarizing and without excluding further possible embodiments, the following embodiments may be envisaged:

Embodiment 1. A system comprising at least one inter-integrated circuit node (I2C node), at least one master controller and at least one inter-integrated circuit (I2C), wherein the I2C is configured for transmitting data between the I2C node and the master controller, wherein the I2C node provides a register map, wherein the master controller is configured for reading the register map byte-wise, wherein the I2C node is configured for incrementing a register address after every byte, wherein the register map comprises a physical register map, wherein data of the physical register map have a physical address in a memory of the I2C node, wherein the I2C node is configured for generating data which size is larger than the physical register map, wherein the register map comprises a virtual section, wherein data of the virtual section have an address in a further memory location, wherein the master controller is configured for reading the virtual section by performing a transaction which starts in the physical register map and increasing the register address beyond the physical register map size.

Embodiment 2. The system according to the preceding embodiment, wherein the I2C node is configured for providing the next data, when the register address reaches the end of the physical register map, by translating between the address in the further memory location and a physical address in the memory.

Embodiment 3. The system according to any one of the preceding embodiments, wherein, when the register address reaches the end of the physical register map, the I2C node is configured for filling the physical register map with values from the virtual section and for resetting the physical address back to zero, wherein this process is transparent for the master controller.

Embodiment 4. The system according to the preceding embodiment, wherein the master controller is configured for reading as many values and/or bytes from the virtual section as required and/or as predefined.

Embodiment 5. The system according to any one of the two preceding embodiments, wherein this process occurs whenever the address in the further memory location reaches a multiple of the size of the physical register map.

Embodiment 6. The system according to any one of the preceding embodiments, wherein the I2C node is configured for operating with at least one special register, wherein, if the master controller starts reading said special register, the I2C node is configured for providing data which are stored in the further memory location, wherein this process is transparent for the master controller.

Embodiment 7. The system according to the preceding embodiment, wherein the I2C node is configured for operating with multiple special registers.

Embodiment 8. The system according to any one of the two preceding embodiments, wherein the special register is one or more of register 0, the final register of the physical register map.

Embodiment 9. The system according to any one of the preceding embodiments, wherein the further memory location is a memory location where all data is available in contiguous form.

Embodiment 10. The system according to any one of the preceding embodiments, wherein the I2C node is configured for providing the physical register map as a standard 8-bit register map, wherein the I2C node is configured for generating data which size N is >256 Byte.

Embodiment 11. The system according to the preceding embodiment, wherein the I2C node comprises at least one sensor, wherein the sensor comprises at least one element selected from the group consisting of: at least one spectrometer, at least one multi-channel IR sensor, at least one multi-channel photo sensor, any sensor with data buffer and automatic data accumulation.

Embodiment 12. The system according to the preceding embodiment, wherein the I2C node is a spectrometer, wherein the spectrometer comprises a number of pixels each with different wavelength filter, so each pixel can measure the light intensity at a certain wavelength.

Embodiment 13. A mobile device comprising at least one system according to any one of the preceding embodiments, wherein the mobile device is at least one element selected from the group consisting of: a notebook computer, a tablet, a cell phone, a smart phone, a smartwatch and a wearable computer, wherein the mobile device is configured for using at least one I2C protocol for data transfer within the mobile device.

Embodiment 14. A method for data transmission between at least one inter-integrated circuit node (I2C node) and at least one master controller, wherein the method comprises using a system according to any one of the preceding embodiments referring to a system, wherein the method comprises the following steps:
generating data which size is larger than the physical register map and providing the register map by using the I2C node;
reading the register map byte-wise by using the master controller and incrementing a register address after every byte by using the I2C node,
reading the virtual section of the register map by performing a transaction which starts in the physical register map and increasing the register address beyond the physical register map size by using the master controller.

Embodiment 15. The method according to the preceding embodiment, wherein the I2C node provides the next data, when the register address reaches the end of the physical register map, by translating between the address in the further memory location and a physical address in the memory.

Embodiment 16. The method according to any one of the preceding embodiments referring to a method, wherein, when the register address reaches the end of the physical register map, the I2C node fills the physical register map with values from the virtual section and resets the physical address back to zero, wherein this process is transparent for the master controller.

Embodiment 17. The method according to the preceding embodiment, wherein the master controller reads as many values and/or bytes from the virtual section as required and/or as predefined.

Embodiment 18. The method according to any one of the two preceding embodiments, wherein this process occurs whenever the address in the further memory location reaches a multiple of the size of the physical register map.

Embodiment 19. The method according to any one of the preceding embodiments referring to a method, wherein the I2C node operates with at least one special register, wherein, if the master controller starts reading said special register, the I2C node provides data which are stored in the further memory location, wherein this process is transparent for the master controller.

Embodiment 20. The method according to any one of the preceding embodiments referring to a method, wherein the method comprises transmission of sensor data generated by the I2C node, wherein the I2C node comprises at least one sensor, wherein the sensor comprises at least one element selected from the group consisting of: at least one spectrometer, at least one multi-channel IR sensor, at least one multi-channel photo sensor, any sensor with data buffer and automatic data accumulation.

Embodiment 21. The method according to the preceding embodiment, wherein the I2C node is a spectrometer, wherein the spectrometer comprises a number of pixels each with different wavelength filter, so each pixel can measure the light intensity at a certain wavelength.

Embodiment 22. The method according to any one of the preceding method embodiments, wherein the method is computer-implemented.

Embodiment 23. A computer program comprising instructions which, when the program is executed by the system according to any one of the preceding embodiments referring to a system, cause the system to perform the method according to any one of the preceding embodiments referring to a method.

Embodiment 24. A computer-readable storage medium comprising instructions which, when the instructions are executed by the system according to any one of the preceding embodiments referring to a system, cause the system to perform the method according to any one of the preceding embodiments referring to a method.

Embodiment 25. A non-transient computer-readable medium including instructions that, when executed by one or more processors, cause the one or more processors to perform the method according to any one of the preceding embodiments referring to a method.

Embodiment 26. Use of a system according to any one of the preceding embodiments referring to a system for a purpose of use, selected from the group consisting of: an infrared detection application; a heat detection application; a thermometer application; a heat-seeking application; a flame-detection application; a fire-detection application; a smoke-detection application; a temperature sensing application; a spectroscopy application; an exhaust gas monitoring application; a combustion process monitoring application; a pollution monitoring application; an industrial process monitoring application; a chemical process monitoring application; a food processing process monitoring application; a water quality monitoring application; an air quality monitoring application; a quality control application; a temperature control application; a motion control application; an exhaust control application; a gas sensing application; a gas analytics application; a motion sensing application; a chemical sensing application; a mobile application; a medical application; a mobile spectroscopy application; a food analysis application.

### SHORT DESCRIPTION OF THE FIGURES

Further optional features and embodiments will be disclosed in more detail in the subsequent description of embodiments, preferably in conjunction with the dependent claims. Therein, the respective optional features may be realized in an isolated fashion as well as in any arbitrary feasible combination, as the skilled person will realize. The scope of the invention is not restricted by the preferred embodiments. The embodiments are schematically depicted in the Figures. Therein, identical reference numbers in these Figures refer to identical or functionally comparable elements.

In the Figures:

FIG. 1 shows an embodiment of a system according to the present invention;

FIGS. 2A and B show data readout;

FIG. 3 shows an embodiment of a method according to the present invention; and

FIG. 4 shows a further embodiment of a method according to the present invention.

### DETAILED DESCRIPTION OF THE EMBODIMENTS

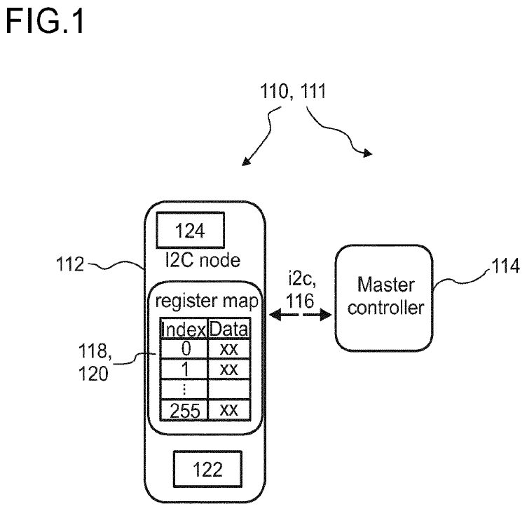

FIG. 1 shows an embodiment of a system 110, e.g. a mobile device 111, according to the present invention. The system 110 comprises at least one inter-integrated circuit node (I2C node) 112, at least one master controller 114 and at least one inter-integrated circuit (I2C) 116. The I2C 116 is configured for transmitting data between the I2C node 112 and the master controller 114. The I2C node 112 provides a register map 118. The master controller 114 is configured for reading the register map 118 byte-wise. The I2C node 112 is configured for incrementing a register address after every byte. The register map 118 comprises a physical register map 120.

Data of the physical register map 120 have a physical address in a memory 122 of the I2C node 112. The I2C node 112 is configured for generating data which size is larger than the physical register map 120. The register map 118 comprises a virtual section. Data of the virtual section have an address in a further memory location 124. The master controller 114 is configured for reading the virtual section by performing a transaction which starts in the physical register map 120. A transaction length of the transaction extends beyond the physical register map size. In particular, the transaction starts at the start address and the transaction length is greater than the size of the physical register map.

The inter-integrated circuit 116 may be a data bus configured for connecting integrated circuits. For example, the I2C 116 may be designed as described in https://www.nxp.com/docs/en/user-guide/UM10204.pdf, www.ipd.kit.edu/˜buchmann/microcontroller/i2c.htm, or in www.ti.com/lit/an/slva704/slva704.pdf. The I2C 116 may be a synchronous, packet switched, single-ended, serial communication bus. Specifically, the I2C 116 is a hierarchical bus system having a so-called master-slave architecture comprising the master controller 114 and the I2C node 112.

The system 110 may comprise one or more I2C nodes 112. The I2C node 112 may be an arbitrary I2C device connected to the I2C bus 116. For example, the I2C node 112 comprises at least one sensor. The sensor may comprise at least one element selected from the group consisting of: at least one spectrometer, at least one multi-channel IR sensor, at least one multichannel photo sensor, any sensor with data buffer and automatic data accumulation (smart sensor). For example, the I2C node 112 is a spectrometer. The spectrometer may comprise a number of pixels each with different wavelength filter, so each pixel can measure the light intensity at a certain wavelength. The I2C node 112 further may comprise at least one processor such as at least one microprocessor, at least one microcontroller and/or at least one computer.

The system may comprise one or more master controllers 114. The master controller 114 may be or may comprise at least one processor such as at least one microprocessor, at least one microcontroller and/or at least one computer assigned to be master of the system. The master controller 114 may be configured for addressing the one or more I2C nodes 112, wherein the reverse is not possible. The I2C 116 is configured for transmitting data between the I2C node 112 and the master controller 114. The transmission may comprise a data exchange. Data may be transferred in sequences of 8 bits. During each clock cycle one data bit may be transferred.

The I2C bus 116 may be based on two lines, wherein one of the lines is used for transporting a clock signal (serial clock line, SCL) and the other one is used for transmitting data bits (serial data line, SDA). The clock signal may be generated by the master controller 114. The master controller 114 may be configured for initiating data transmission by sending a query to an I2C node 112. To start a data transmission, the master controller 114 may be configured for specifying an address of the I2C node 112 to or from which it wants to exchange data. Each I2C node 112 may comprise an, in particular 4-bit, address hard-wired into a chip of the I2C node 112. In addition, the chip of each I2C node 112 may comprise a plurality of address pins, which can be assigned with any address. For addressing the respective I2C node 112 a plurality of bits, e.g. 7 bits, may be used and transferred. At least one further bit may be used for specifying whether the master controller 114 is to transmit data to the I2C node 112 (i.e. write) or to receive data from the I2C node 112 (i.e. read). As described in www.ti.com/lit/an/slva704/slva704.pdf, a procedure for the master controller 114 to read data from the I2C node may be as follows
the master controller 114 sends a START condition and addresses the I2C node 112, wherein a high-to-low transition on the SDA line while the SCL is high defines a START condition;
the master controller 114 sends the requested register to read from to the I2C node 112;
the master controller 114 receives data from the I2C node 112;
the master controller 114 terminates the transfer with a STOP condition, wherein a low-to-high transition on the SDA line while the SCL is high defines a STOP condition.

The I2C node 112 may comprise one or more registers. The register may be a location in a memory 122, 124 of the I2C node 112 configured for storing information. The information may be configuration information and/or data obtained by the at least one sensor of the I2C node 112. The information stored within the register may be values, in particular one or more of measurement values, measurement uncertainties, calibration values, (system) configuration values, measurement parameters. Each of the registers may have a unique address. Each of the registers may comprise 8 bits. The master controller 114 is configured for reading, and optionally writing into, the register map byte-wise. The master controller 114 can read and write into the register map byte-wise. The I2C node 112 is configured for incrementing a register address after every byte.

Usually, reading from a register may be performed as follows, e.g. as described in www.ti.com/lit/an/slva704/slva704.pdf. The master controller 114 may be configured for instructing the I2C node 112 from which register map 118 it wishes to read from. The master controller 114 may be configured for starting off the transmission by sending the address with the bit signifying a write, followed by the register address it wishes to read from. After the I2C node 112 acknowledges this register address, the master controller 114 may send a START condition again, followed by the I2C node address with the bit signifying a read. The I2C node 112 may acknowledge the read request. The master controller 114 may continue sending out the clock pulses, but will release the SDA line, so that the I2C node 112 can transmit data. At the end of every Byte of data, the master controller 114 may send an ACK (acknowledge) to the I2C node, letting the I2C node 112 know that it is ready for more data. Once the master controller 114 may have received the number of bytes it is expecting, it will send a NACK (Not Acknowledge), signaling to the I2C node 112 to halt communications and release the bus. The master controller 114 may follow this up with a STOP condition. The master controller 114 can read and write into the register map 118 byte-wise. The I2C node 112 may be configured for automatically incrementing the address after every byte so that a single transaction can include more than one byte.

As outlined above, the I2C node 112 provides a register map 118. The register map may be an ordered list of registers. The I2C node 112 may comprise one or more registers. Each of the registers may have a unique address. The register map 118 may comprise a register map layout. The register map 118 may comprise a plurality of columns and rows. The register map 118 may comprise an index N for each register. For example, as shown in FIG. 1, the register map 118 may comprise two columns, wherein in a first column the index and in a second column a register name is listed. The register map 118 may comprise a size. The size of the index N may be equal to the size of the register map 118.

The register map 118 comprises the physical register map 120. Data of the physical register map 120 have a physical address in the memory 122 of the I2C node 112. The I2C node 112 is configured for generating data which size is larger than the physical register map 120. The physical register map 120 may be a part of the register map 118 comprising registers having a physical address in the memory 122 of the I2C node 112. The memory 122 may be or may comprise a device or system configured for storing data. The memory 122 may comprise semiconductor memory. The memory 122 of the I2C node 112 may comprise volatile and/or non-volatile memory. For example, the memory 122 of the I2C node 112 may comprise one or more of RAM such as dynamic random-access memory (DRAM) or static random-access memory (SRAM). For example, the memory 122 of the I2C node 112 may comprise one or more of flash memory, ROM, PROM, EPROM, EEPROM memory and Ferroelectric random-access memory (FRAM). The physical register map 120 may comprise a physical register map size. The I2C node 112 is configured for providing the physical register map 120 as a standard 8-bit register map. The physical register map size may be N≤256. The I2C node 112 may be configured for generating data which size N is >256 Byte.

Usually, the size of the physical register map 120 size, is 256 Byte, wherein the index N may run from 0 to 255. However, the I2C node 112 may generate data which size is larger than the physical register map 120 (e.g. more than 256 Byte) (size N>256). In this case, for example, the register map size may be increased. However, this may not be possible under certain circumstances e.g. in case the I2C node 112 does not have enough RAM or the register address size is fixed to 8-bit due to software compatibility. Additionally or alternatively, the register map 118 may be partitioned into smaller sizes and data transmission may be performed using multiple transactions. The following table shows an example of this:

| Register | Content |
|---|---|
| Register 0 | Partition index |
| Register 1 | Result value 0 |
| . | . |
| . | . |
| . | . |
| Register | Result value |
| 254 | 253 |
| Register | Result value |
| 255 | 254 |

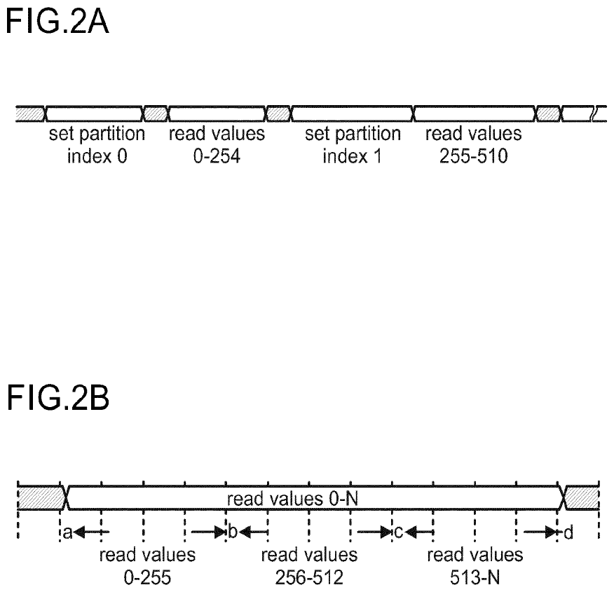

For example, the data is partitioned into smaller sizes that fit into the register map 118, e.g. in sizes of 128 Byte values. The register map 118 may comprise a special control register named “partition index” which controls which partition is accessed by the master controller. To read all data, the master controller may first perform a write transaction to the partition index followed by a read transaction which can transport up to 254 Bytes. This pair of transactions must be performed multiple times, until all data is transferred. Thus, if the data is partitioned and a partition index is used, then multiple transactions must be performed. Such a data transfer is shown in FIG. 2A. However, in case of partitioning gaps in the transfer between the transactions. Between every transaction is a gap, due to one or more of a) the bus possibly being used for another sensor, b) natural processing delay, i.e. starting a new transaction takes several CPU cycles and c) the process requesting the next transfer sleeping and waiting to be scheduled again (on systems with operating system). The contribution of a) and b) mainly depend on the system load and the processor performance. Depending on the number of bytes and the operating system, these gaps can become significant (e.g. non real time operating system like Linux, Android).

Specifically, in order to allow fast readout although the I2C node 112 generating data which size is larger than the physical register map 120, the present invention proposes the register map 118 comprising the virtual section. The register map 118 may be extended virtually. Data of the virtual section have an address in the further memory location 124. The virtual section may be a further part of the register map 118, i.e. in addition to the physical register map 120, comprising registers having an address in the further memory location 124. The further memory location 124 may be a physical storage location of the I2C node 112 different from the memory 122. The further memory location 124 may be a memory location where all data is available in contiguous form. Due to the contiguous form, the I2C node 112 can provide all data for reading in a single transaction.

The following table shows an exemplary register map layout with a virtual extension:

| Register | Content | Remarks |
|---|---|---|
| Register 0 | Result value 0 | Start of physical register map |
| Register 1 | Result value 1 | |
| . | . | |
| . | . | |
| . | . | |
| Register 254 | Result value 254 | |
| Register 255 | Result value 255 | End of physical register map |
| Register 256 | Result value 256 | Start of virtual section |
| Register 257 | Result value 257 | |
| . | . | |
| . | . | |
| . | . | |
| Register N | Result value N | End of virtual section |

The virtual section cannot be addressed directly. The master controller 114 is configured for reading the virtual section by performing a transaction which starts in the physical register map 120. A transaction length of the transaction extends beyond the physical register map size. To read all data generated by the I2C node 112, the master controller 114 may start reading the first value (e.g. register address 0) and may keep reading even after reading value 255 until all data of the registers of the virtual section, e.g. values 256 to N with N>256, is transferred. By this technique, all data is transferred in a single read transaction. Extending the register map virtually may allow providing the fastest possible solution to transfer all data. Such a data transfer is shown in FIG. 2B.

As outlined above, the I2C node 112 may be configured for automatically incrementing the address after every Byte. When the address reaches the end of the physical register map 120, it cannot fetch the data from the next consecutive physical address. The I2C node 112 may be configured for providing the next data from the first register of the virtual section. The I2C node 112 may be configured for providing the next data, when the register address reaches the end of the physical register map 120, by translating between the address in the further memory location 124 and a physical address in the memory 122.

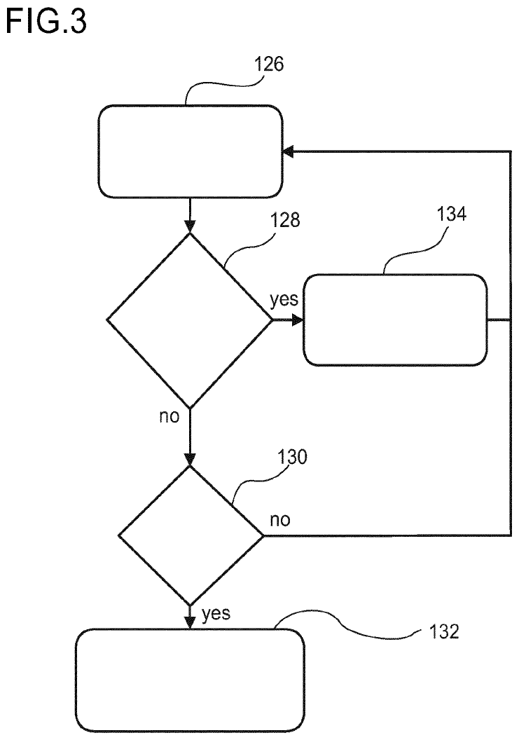

For example, as shown in FIG. 3, the master controller may reads 1 byte out of N bytes (reference number 126). If the end of the register map (reference number 128) is not reached when the transfer is ended (reference number 130), the I2C node 112 will update and/or refill the physical register map 120 with the original values for page 0 (reference number 132). If the end of the register map (reference number 128) is not reached and the transfer is not ended (reference number 130), the master controller will continue reading 1 byte out of N bytes (reference number 126). If the end of the register map (reference number 128), however, is reached before the end of the transfer, the I2C node 112 may be configured for filling and/or updating the physical register map 120 with values from the virtual section (reference number 134) and for resetting the physical address back to zero, when the register address reaches the end of the physical register map 120 (reference number 128). This process may be transparent for the master controller 114. The master controller 114 may be configured for reading as many values and/or bytes from the virtual section as required and/or as predefined, e.g. through a driver. This process may occur whenever the address in the further memory location 124 reaches a multiple of the size of the physical register map 120. The I2C node 112 may be configured for updating and/or refilling the physical register map 120 with the original values for page 0, after the transfer is completed (reference number 132).

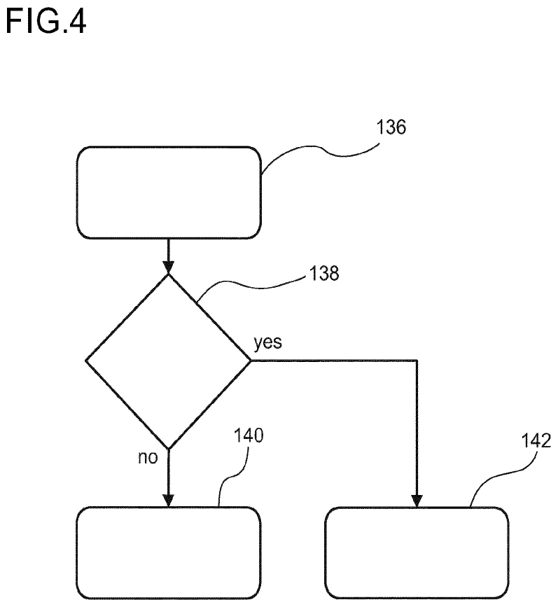

FIG. 4 shows a further embodiment, in which the I2C node 112 may be configured for operating with at least one special register. The I2C node 112 may be configured for operating with multiple special registers. The virtual extension of the physical register map 120 may only be available if the read starts from a special (or one of multiple special registers). The special register may be a register of the physical register map 120 having a predefined and/or preassigned function. The special register may be any register or multiple register in the physical register map 120. The special register may be register 0. Other embodiments are possible. For example, the special register may be placed after all register values (if there are any) of the physical register map. The I2C node 112 may be configured for providing data which are stored in the further memory location 124, if the master controller 114 starts reading said special register. This may also be transparent for the master controller 114. For example, once the master controller 114 may start reading exactly the special register, the I2C node 112 may send data internally which are stored in a different storage location. If the read starts from the special register, the I2C node 112 may fetch data not from the physical register map 120, but instead from a special memory location where all data is available in contiguous form. The address in the further memory location 124 may be defined by another register, e.g. an offset from the location of the special register. As shown in FIG. 4, in step 136, the master controller reads N bytes. If the special register is not reached (reference number 138), the I2C node sends data from physical register map (reference number 140). If the special register is reached (reference number 138), the I2C node sends data from the further memory location (reference number 142).

### LIST OF REFERENCE NUMBERS

110 system
111 mobile device
112 I2C node
114 master controller
116 I2C
118 register map
120 physical register map
122 memory
124 further memory location
126 master controller reads 1 byte out of N bytes
128 end of the register map
130 transfer finished
132 updating and/or refilling the physical register map
134 filling and/or updating the physical register map 120 with values from the virtual section
136 the master controller reads N bytes
138 special register reached?
140 I2C node sends data from physical register map
142 I2C node sends data from the further memory location

1. A system comprising at least one inter-integrated circuit node (I2C node), at least one master controller and at least one inter-integrated circuit (I2C), wherein the I2C is configured for transmitting data between the I2C node and the master controller, wherein the I2C node provides a register map, wherein the master controller is configured for reading the register map byte-wise, wherein the I2C node is configured for incrementing a register address after every byte, wherein the register map comprises a physical register map, wherein data of the physical register map have a physical address in a memory of the I2C node, wherein the I2C node is configured for generating data which size is larger than the physical register map, wherein the register map comprises a virtual section, wherein data of the virtual section have an address in a further memory location, wherein the master controller is configured for reading the virtual section by performing a transaction which starts in the physical register map, and wherein a transaction length of the transaction extends beyond the physical register map size.

2. The system according to claim 1, wherein the I2C node is configured for providing the next data, when the register address reaches the end of the physical register map, by translating between the address in the further memory location and a physical address in the memory.

3. The system according to claim 1, wherein, when the register address reaches the end of the physical register map, the I2C node is configured for filling the physical register map with values from the virtual section and for resetting the physical address back to zero, wherein this process is transparent for the master controller.

4. The system according to claim 3, wherein the master controller is configured for reading as many values and/or bytes from the virtual section as required and/or as predefined.

5. The system according to claim 3, wherein this process occurs whenever the address in the further memory location reaches a multiple of the size of the physical register map.

6. The system according to claim 1, wherein the I2C node is configured for operating with at least one special register, wherein, if the master controller starts reading said special register, the I2C node is configured for providing data which are stored in the further memory location, wherein this process is transparent for the master controller.

7. The system according to claim 1, wherein the further memory location is a memory location where all data is available in contiguous form.

8. The system according to claim 7, wherein the I2C node comprises at least one sensor, wherein the sensor comprises at least one element selected from the group consisting of: at least one spectrometer, at least one multichannel IR sensor, at least one multi-channel photo sensor, and any sensor with data buffer and automatic data accumulation.

9. A mobile device comprising at least one system according to claim 1, wherein the mobile device is at least one element selected from the group consisting of: a notebook computer, a tablet, a cell phone, a smart phone, a smartwatch and a wearable computer, wherein the mobile device is configured for using at least one I2C protocol for data transfer within the mobile device.

10. A method for data transmission between at least one inter-integrated circuit node and at least one master controller, wherein the method comprises using a system according to claim 1, wherein the method comprises the following steps:
generating data which size is larger than the physical register map and providing the register map by using the I2C node;
reading the register map byte-wise by using the master controller and incrementing a register address after every byte by using the I2C node, and
reading the virtual section of the register map by performing a transaction which starts in the physical register map, by using the master controller, wherein a transaction length of the transaction extends beyond the physical register map size.

11. The method according to claim 10, wherein the method is computer-implemented.

12. A computer program comprising instructions which, when the program is executed by the system according to claim 1, cause the system to perform a method for data transmission between at least one inter-integrated circuit node (I2C node) and at least one master controller, wherein the method comprises the following steps:
generating data which size is larger than the physical register map and providing the register map by using the I2C node;
reading the register map byte-wise by using the master controller and incrementing a register address after every byte by using the I2C node, and
reading the virtual section of the register map by performing a transaction which starts in the physical register map, by using the master controller, wherein a transaction length of the transaction extends beyond the physical register map size.

13. A computer-readable storage medium comprising instructions which, when the instructions are executed by the system according to claim 1, cause the system to perform a method for data transmission between at least one inter-integrated circuit node (I2C node) and at least one master controller, wherein the method comprises the following steps:
generating data which size is larger than the physical register map and providing the register map by using the I2C node;
reading the register map byte-wise by using the master controller and incrementing a register address after every byte by using the I2C node, and
reading the virtual section of the register map by performing a transaction which starts in the physical register map, by using the master controller, wherein a transaction length of the transaction extends beyond the physical register map size.

14. A non-transient computer-readable medium including instructions that, when executed by one or more processors, cause the one or more processors to perform the method according to claim 10.

15. A method of using a system according to claim 1, the method comprising using the system for a purpose of use selected from the group consisting of: an infrared detection application; a heat detection application; a thermometer application; a heat-seeking application; a flame-detection application; a fire-detection application; a smoke-detection application; a temperature sensing application; a spectroscopy application; an exhaust gas monitoring application; a combustion process monitoring application; a pollution monitoring application; an industrial process monitoring application; a chemical process monitoring application; a food processing process monitoring application; a water quality monitoring application; an air quality monitoring application; a quality control application; a temperature control application; a motion control application; an exhaust control application; a gas sensing application; a gas analytics application; a motion sensing application; a chemical sensing application; a mobile application; a medical application; a mobile spectroscopy application; and a food analysis application.
